(19) United States
(12) Patent Application Publication
(10) Pub. No.: US 2022/0007530 A1
(43) Pub. Date: Jan. 6, 2022

(54) COVER PLATE AND FLEXIBLE DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Ping HE, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/645,693

(22) PCT Filed: Dec. 20, 2019
(86) PCT No.: PCT/CN2019/126912

§ 371 Date: Mar. 9, 2020

(30) Foreign Application Priority Data
Aug. 30, 2019 (CN) 201910812634.X

(51) Int. Cl. H05K 5/03

(52) U.S. Cl. CPC H05K 5/03

(57) ABSTRACT

The present invention provides a cover plate including a non-bending region and a bending region connected to the non-bending region. A hardness of a portion of the cover plate disposed in the bending region is less than a hardness of a portion of the cover plate disposed in the non-bending region.

This application claims priority to Chinese Patent Application No. 201910812634.X, entitled “Cover Plate and Flexible Display Device” in Chinese Priority Patent Application, filed on Aug. 30, 2019, the entire disclosure of which is incorporated by reference in its entirety.

### FIELD OF INVENTION

The present invention relates to the field of display technologies, and in particular, to a cover plate and a flexible display device.

### BACKGROUND OF INVENTION

OLED displays are widely used in flexible display products such as foldable mobile phones, smart watches, and in-vehicle displays due to their advantages such as thinness, flexibility, and foldability. In order to achieve overall bendable performance, each film layer of OLED display modules needs to use flexible materials. At the same time, how to improve impact resistance of display modules has become an important technical problem in flexible OLED displays.

In prior art, flexible OLED display devices use flexible substrates as cover plates to protect display panels. A layer of foam is attached to contact parts of a display panel and middle frames of a whole device to provide cushion effects. However, some film layers such as thin film encapsulation layers and organic light emitting layers inside display panels are not ideal enough to withstand impact energy. When subjected to falling ball impact, some film layers such as the thin film encapsulation layers and the organic light emitting layers in the flexible display panels cannot withstand excessive impact, which may cause damage to the flexible display devices.

In summary, the cover plates of flexible display devices in prior art, due to the use of flexible substrates, cause flexible display devices to have insufficient impact resistance, which causes a problem that flexible display devices are easily damaged. Therefore, it is necessary to improve this defect.

### Technical Problem

Due to the use of flexible substrates in the cover plates of flexible display devices in prior art, impact resistance of the flexible display devices is insufficient, and a technical problem that flexible display devices are easily damaged is caused.

### Technical Solution

In order to solve the above problems, the technical solution provided by the present invention is as follows:

An embodiment of the present invention provides a cover plate comprising a non-bending region and a bending region connected to the non-bending region; wherein a hardness of a portion of the cover plate disposed in the bending region is less than a hardness of a portion of the cover plate disposed in the non-bending region.

In the cover plate provided in the embodiment of the present invention, a flexible material and a rigid material are arranged spaced apart from each other in the bending region, and a material in the non-bending region is the rigid material, or a combination of the flexible material and the rigid material.

In the cover plate provided in the embodiment of the present invention, a groove is formed in a side of the non-bending region connecting to the bending region, and the flexible material of the bending region extends into the groove.

In the cover plate provided in the embodiment of the present invention, a cross-sectional shape of the groove is triangular, rectangular, or fan-shaped.

In the cover plate provided in the embodiment of the present invention, a depth of the groove is less than or equal to a thickness of the cover plate.

In the cover plate provided in the embodiment of the present invention, the flexible material and the rigid material of the non-bending region are stacked on each other.

In the cover plate provided in the embodiment of the present invention, the flexible material of the non-bending region is disposed on an inner surface or an outer surface of the cover plate.

In the cover plate provided in the embodiment of the present invention, the flexible material in the non-bending region is disposed between two layers of the rigid material.

In the cover plate provided in the embodiment of the present invention, a cross-sectional shape of the rigid material of the bending region is inverted-triangular or trapezoidal.

An embodiment of the present invention provides a flexible display device comprising a display panel and a cover plate disposed on a light emitting surface of the display panel; wherein the cover plate comprises a non-bending region and a bending region connected to the non-bending region, and a hardness of a portion of the cover plate disposed in the bending region is less than a hardness of a portion of the cover plate disposed in the non-bending region.

In the flexible display device provided in the embodiment of the present invention, a flexible material and a rigid material are arranged spaced apart from each other in the bending region, and a material in the non-bending region is the rigid material, or a combination of the flexible material and the rigid material.

In the flexible display device provided in the embodiment of the present invention, a groove is formed in a side of the non-bending region connecting to the bending region, and the flexible material of the bending region extends into the groove.

In the flexible display device provided in the embodiment of the present invention, a cross-sectional shape of the groove is triangular, rectangular or fan-shaped.

In the flexible display device provided in the embodiment of the present invention, a depth of the groove is less than or equal to a thickness of the cover plate.

In the flexible display device provided in the embodiment of the present invention, the flexible material and the rigid material of the non-bending region are stacked on each other.

In the flexible display device provided in the embodiment of the present invention, the flexible material of the non-bending region is disposed on an inner surface or an outer surface of the cover plate.

In the flexible display device provided in the embodiment of the present invention, the flexible material in the non-bending region is disposed between two layers of the rigid material.

In the flexible display device provided in the embodiment of the present invention, a cross-sectional shape of the rigid material of the bending region is an inverted-triangular or trapezoidal.

### Beneficial Effect

Compared with the prior art, a cover plate provided in an embodiment of the present invention uses a hard-soft-hard structure, that is, a material with higher strength is used at non-bending regions on both sides, and a material with lower strength is used in a middle bending region. With the structure, impact strength of the non-bending regions of a flexible display device can be improved.

### DESCRIPTION OF DRAWINGS

FIG. 1 is a basic structural view of a cover plate provided in embodiment 1 of the present invention.

FIG. 2 is a basic structural view of a cover plate provided in embodiment 2 of the present invention.

FIG. 3 is a basic structural view of a cover plate provided in embodiment 3 of the present invention.

FIG. 4 is a basic structural view of a cover plate provided in embodiment 4 of the present invention.

FIG. 5 is a basic structural view of a cover plate provided in embodiment 5 of the present invention.

FIG. 6 is a basic structural view of a cover plate provided in embodiment 6 of the present invention.

FIG. 7 is a structural view of a bending region of a cover plate provided in an embodiment of the present invention.

FIG. 8 is a basic structural view of a flexible display device provided by an embodiment of the present invention.

### DETAILED DESCRIPTION OF PREFERRED EMBODIMENTS

The present invention provides a cover plate and a flexible display device. In order to make the purpose, technical solution, and effect of the present invention clearer and more definite, the following describes the present invention in detail with reference to the accompanying drawings and examples.

An embodiment of the present invention provides a cover plate comprising a non-bending region and a bending region connected to the non-bending region. A hardness of a portion of the cover plate disposed in the bending region is less than a hardness of a portion of the cover plate disposed in the non-bending region. By using a hard-soft-hard structure, that is, a material with higher strength is used at non-bending regions on both sides, and a material with lower strength is used in a middle bending region, with the structure, impact strength of the non-bending regions of a flexible display device can be improved.

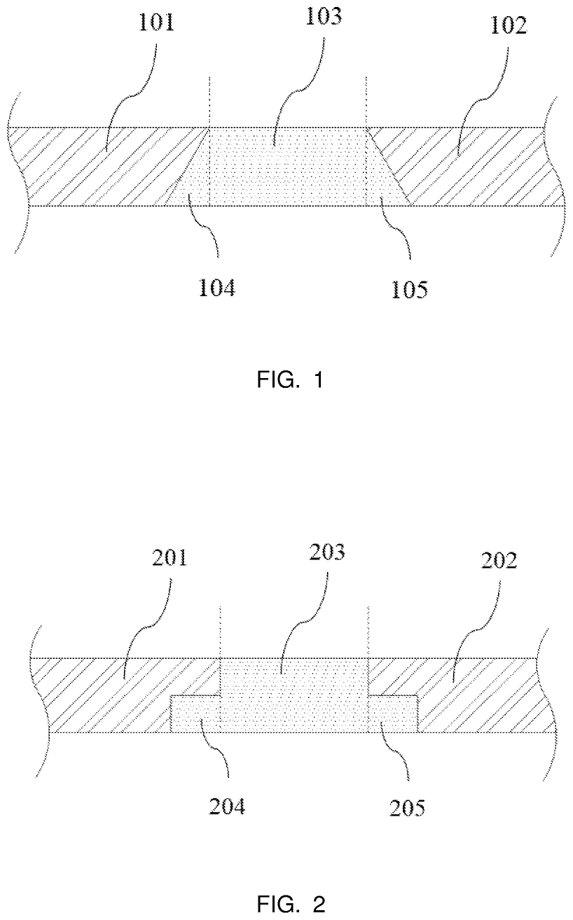

As shown in FIG. 1, which is a basic structural view of a cover plate provided in embodiment 1 of the present invention. From the figure, each component of the present invention and relative position relationships between the components can be directly perceived. The cover plate comprises a first non-bending region 101, a second non-bending region 102, and a bending region 103 connecting the first non-bending region 101 and the second non-bending region 102. A hardness of a portion of the cover plate in the bending region 103 is less than a hardness of a portion of the cover plate in the first non-bending region 101 and a hardness of a portion of the second non-bending region 102.

Specifically, the bending region 103 comprises a flexible material and a rigid material (not shown in the figure) arranged spaced apart from each other. A material in the first non-bending region 101 and the second non-bending region 102 is a rigid material, or a combination of a flexible material and a rigid material. The first non-bending region 101 and the second non-bending region 102 of the cover plate of the embodiment are made of a rigid material or a combination of a flexible material and a rigid material, which can improve impact strength of the non-bending region of the flexible display device. And based on this, the bending region 103 is designed as a rigid-flexible alternating structure, which ensures that impact resistance of the bending region 103 is improved as much as possible without affecting the bending, that is, overall impact resistance of the flexible display device is improved.

In an embodiment, a first groove 104 and a second groove 105 are formed on a side of the first non-bending region 101 and the second non-bending region 102 connected to the bending region 103. The flexible material of the bending region 103 extends into the first groove 104 and the second groove 105. A depth of the first groove 104 and the second groove 105 is less than or equal to a thickness of the cover plate.

In an embodiment, a cross-sectional shape of the first groove 104 and the second groove 105 is triangular. In this way, contact areas between the first non-bending region 101 and the flexible material in the bending region 103 and contact areas between the second non-bending region 102 and the flexible material in the bending region 103 may be increased, a connection stability between the non-bending region and the bending region may be enhanced, and a part of bending stress can also be shared.

In an embodiment, a high strength glass material is used in the first non-bending region 101 and the second non-bending region 102 on the both sides of the cover plate, and the flexible material is used in the middle bending region 103. For example, polyimide, polyethylene terephthalate, etc. A transition region of the two materials can be connected by offset edge overlapping or micro-hole treatment directly by optical glue. Compared with the prior art, the non-bending regions on the two sides of the cover plate of the embodiment can be directly fixed with high temperature glue with a whole device, an operation is simple, and an adhesion stability is improved.

It should be noted that there is more than one bending region in the embodiment, and there may be two or more regions. Accordingly, there are more than two non-bending regions connected to the bending region, which may be three or more. A connection between the non-bending region and the bending region is similar to the above structure. The transition region can be connected by the offset edge overlapping or the micro-hole treatment directly by the optical glue.

As shown in FIG. 2, which is a basic structural view of a cover plate provided in embodiment 2 of the present invention. From the figure, each component of the present invention and relative position relationships between the components can be directly perceived. The cover plate comprises a first non-bending region 201, a second non-bending region 202, and a bending region 203 connected to the first non-bending region 201 and the second non-bending region 202. A hardness of a portion of the cover plate in the bending region 203 is less than a hardness of a portion of the cover plate in the first non-bending region 201 and a hardness of a portion of the second non-bending region 202.

In an embodiment, a first groove 204 and a second groove 205 are formed on a side of the first non-bending region 201 and the second non-bending region 202 connected to the bending region 203. A flexible material of the bending region 203 extends into the first groove 204 and the second groove 205. A depth of the first groove 204 and the second groove 205 is less than or equal to a thickness of the cover plate. A cross-sectional shape of the first groove 204 and the second groove 205 is rectangular. In this way, contact areas between the first non-bending region 101 and the flexible material in the bending region 103, and contact areas between the second non-bending region 102 and the flexible material in the bending region 103 may be increased, a connection stability between the non-bending region and the bending region may be enhanced, and a part of bending stress can also be shared.

In an embodiment, a high strength glass material is used in the first non-bending region 101 and the second non-bending region 102 on the both sides of the cover plate, and the flexible material is used in the middle bending region 103. For example, polyimide, polyethylene terephthalate, etc. A transition region of the two materials can be connected by offset edge overlapping or micro-hole treatment directly by optical glue. Compared with the prior art, the non-bending regions on the two sides of the cover plate of the embodiment can be directly fixed with high temperature glue with a whole device, an operation is simple, and an adhesion stability is improved.

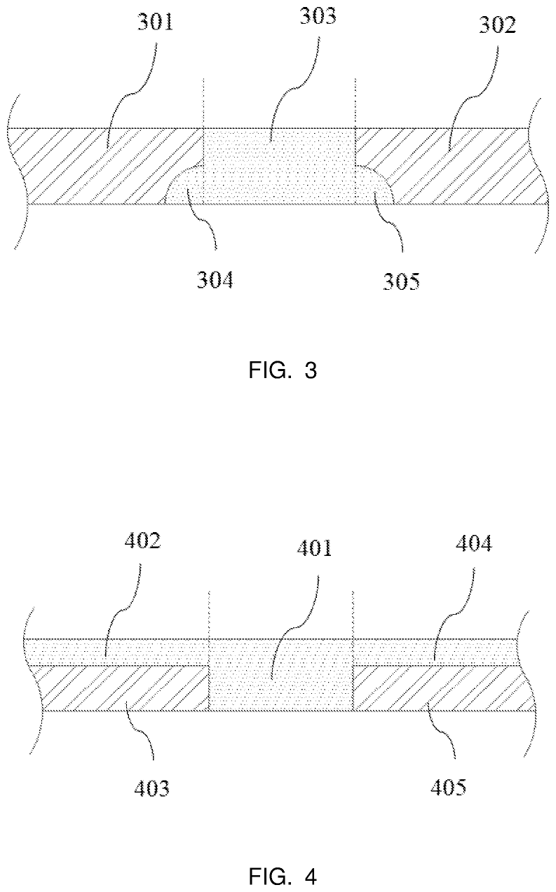

As shown in FIG. 3, which is a basic structural view of a cover plate provided in embodiment 3 of the present invention. From the figure, each component of the present invention and relative position relationships between the components can be directly perceived. The cover plate comprises a first non-bending region 301, a second non-bending region 302, and a bending region 303 connected to the first non-bending region 301 and the second non-bending region 302. A hardness of a portion of the cover plate in the bending region 303 is less than a hardness of a portion of the cover plate in the first non-bending region 301 and a hardness of a portion of the second non-bending region 302.

In an embodiment, a first groove 304 and a second groove 305 are formed on a side of the first non-bending region 301 and the second non-bending region 302 connected to the bending region 303. A flexible material of the bending region 303 extends into the first groove 304 and the second groove 305. A depth of the first groove 304 and the second groove 305 is less than or equal to a thickness of the cover plate, and cross-sectional shapes of the first groove 304 and the second groove 305 are fan-shaped. In this way, contact areas between the first non-bending region 301 and the flexible material in the bending region 303, and contact areas between the second non-bending region 302 and the flexible material in the bending region 303 may be increased, a connection stability between the non-bending region and the bending region may be enhanced, and a part of bending stress can also be shared.

In an embodiment, a high strength glass material is used in the first non-bending region 301 and the second non-bending region 302 on the both sides of the cover plate, and the flexible material is used in the middle bending region 303. For example, polyimide, polyethylene terephthalate, etc. A transition region of the two materials can be connected by offset edge overlapping or micro-hole treatment directly by optical glue. Compared with the prior art, the non-bending regions on the two sides of the cover plate of the embodiment can be directly fixed with high temperature glue with a whole device, an operation is simple, and an adhesion stability is improved.

As shown in FIG. 4, which is a basic structural view of a cover plate provided in embodiment 4 of the present invention. From the figure, each component of the present invention and relative position relationships between the components can be directly perceived. The cover plate comprises a first non-bending region, a second non-bending region, and a bending region 401 connected to the first non-bending region and the second non-bending region. A hardness of a portion of the cover plate in the bending region 401 is less than a hardness of a portion of the cover plate in the first non-bending region and a hardness of a portion of the second non-bending region. The bending region 401 comprises a flexible material and a rigid material (not shown in the figure) arranged spaced apart from each other, and the flexible material and the rigid material in the first non-bending region and the second non-bending region are stacked on each other.

In an embodiment, a flexible material 402 of the first non-bending region is disposed on an outer surface of the cover plate, and a rigid material 403 of the first non-bending region is disposed on an inner surface of the cover plate and is in contact with the flexible material 402. A flexible material 404 of the second non-bending region is disposed on the outer surface of the cover plate, and a rigid material 405 of the second non-bending region is disposed on the inner surface of the cover plate and is in contact with the flexible material 404. That is, a lower part of the non-bending region of the cover plate in a thickness direction is reinforced with a rigid material. When impacted by a small ball, the rigid material at a bottom can absorb most energy to avoid damage to the flexible display device.

In an embodiment, the rigid material 403 in the first non-bending region and the rigid material 405 in the second non-bending region are glass materials with higher strength. The flexible material 402 in the first non-bending region, the flexible material 404 in the second non-bending region, and the flexible material in the bending region 401 are polyimide or polyethylene terephthalate. A transition region of the two materials can be connected by offset edge overlapping or micro-hole treatment directly by optical glue. Compared with the prior art, the non-bending regions on the two sides of the cover plate of the embodiment can be directly fixed with high temperature glue with a whole device, an operation is simple, and an adhesion stability is improved. The manufacturing process is to first fix the rigid material 403 and the rigid material 405 with a preset width as a relative distance, and then fill the bending region 401 and the non-bending region of the flexible material.

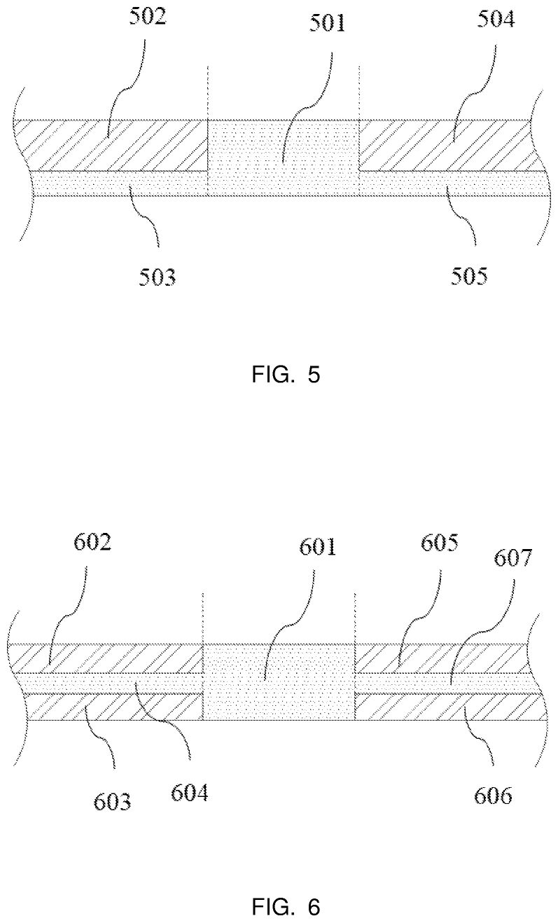

As shown in FIG. 5, which is a basic structural view of a cover plate provided in embodiment 5 of the present invention. From the figure, each component of the present invention and relative position relationships between the components can be directly perceived. The cover plate comprises a first non-bending region, a second non-bending region, and a bending region 501 connected to the first non-bending region and the second non-bending region. A hardness of a portion of the cover plate in the bending region 501 is less than a hardness of a portion of the cover plate in the first non-bending region and a hardness of a portion of the second non-bending region. The bending region 501 comprises a flexible material and a rigid material (not shown in the figure) arranged spaced apart from each other, and the flexible material and the rigid material in the first non-bending region and the second non-bending region are stacked on each other.

In an embodiment, a rigid material 502 of the first non-bending region is disposed on an outer surface of the cover plate, and a flexible material 503 of the first non-bending region is disposed on an inner surface of the cover plate and is connected to the rigid material 502. A rigid material 504 of the second non-bending region is disposed on an outer surface of the cover plate, and a flexible material 505 of the second non-bending region is disposed on an inner surface of the cover plate and is connected to the rigid material 504. That is, an upper part of the non-bending region of the cover plate in a thickness direction is reinforced with a rigid material. When impacted by a small ball, the rigid material on a top can not only absorb most energy and avoid damage to the flexible display device but also improve friction resistance of the outer surface of the cover plate.

In an embodiment, the rigid material 502 in the first non-bending region and the rigid material 504 in the second non-bending region are glass materials with higher strength. The flexible material 503 in the first non-bending region, the flexible material 505 in the second non-bending region, and the flexible material in the bending region 501 are polyimide or polyethylene terephthalate. A transition region of the two materials can be connected by offset edge overlapping or micro-hole treatment directly by optical glue. Compared with the prior art, the non-bending regions on the two sides of the cover plate of the embodiment can be directly fixed with high temperature glue with a whole device, an operation is simple, and an adhesion stability is improved. The manufacturing process is to first fix the rigid material 502 and the rigid material 504 with a preset width as a relative distance, and then fill the bending region 501 and the non-bending region of the flexible material.

As shown in FIG. 6, which is a basic structural view of a cover plate provided in embodiment 6 of the present invention. From the figure, each component of the present invention and relative position relationships between the components can be directly perceived. The cover plate comprises a first non-bending region, a second non-bending region, and a bending region 601 connected to the first non-bending region and the second non-bending region. A hardness of a portion of the cover plate in the bending region 601 is less than a hardness of a portion of the cover plate in the first non-bending region and a hardness of a portion of the second non-bending region. The bending region 601 comprises a flexible material and a rigid material (not shown in the figure) arranged spaced apart from each other, and the flexible material and the rigid material in the first non-bending region and the second non-bending region are stacked on each other.

In an embodiment, a flexible material 604 of the first non-bending region is disposed between a first rigid material 602 and a second rigid material 603. A flexible material 607 of the second non-bending region is disposed between a third rigid material 605 and a fourth rigid material 606. That is, an outer surface and an inner surface of the non-bending region of the cover plate are reinforced with a rigid material. When impacted by a small ball, the double-layer rigid material can absorb more energy to avoid damage to the flexible display device.

In an embodiment, the first rigid material 602, the second rigid material 603, the third rigid material 605, and the fourth rigid material 606 are glass materials with higher strength. The flexible material 604 in the first non-bending region, the flexible material 607 in the second non-bending region, and the flexible material in the bending region 601 are polyimide or polyethylene terephthalate. A transition region of the two materials can be connected by offset edge overlapping or micro-hole treatment directly by optical glue. Compared with the prior art, the non-bending regions on the two sides of the cover plate of the embodiment can be directly fixed with high temperature glue with a whole device, an operation is simple, and an adhesion stability is improved.

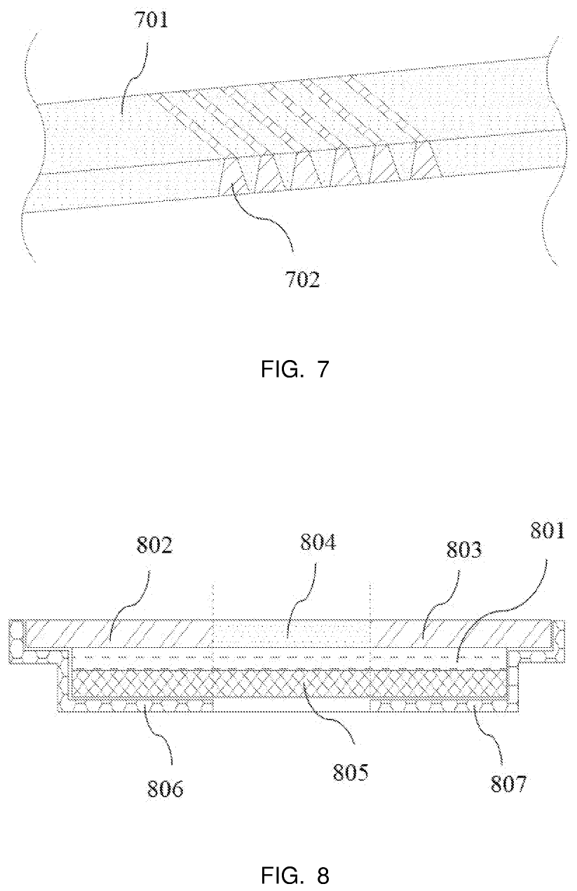

As shown in FIG. 7, which is a structural view of a bending region of the cover plate provided in the embodiment of the present invention. The bending region of the cover plate comprises a flexible material 701 and a rigid material 702 arranged spaced apart from each other. The rigid material 702 of the bending region is inverted-triangular or trapezoidal.

In an embodiment, the flexible material 701 is polyimide or polyethylene terephthalate. The rigid material 702 is tempered glass. This glass strip structure can make a natural transition between the non-bending region and the bending region on the cover surface when the display device is flattened, reduce a difference in touch when pressing different regions, and meet bendable performance. In addition, by connecting the glass strip structure to an entire chassis or a rotating shaft of the flexible display device, impact resistance of the bending region can also be improved.

As shown in FIG. 8, which is a basic structural view of a flexible display device provided by an embodiment of the present invention. From the figure, each component of the present invention and relative position relationships between the components can be directly perceived. The flexible display device comprises a display panel 801, a cover plate, and a middle frame. The cover plate is disposed on a light emitting surface of the display panel 801. The cover plate comprises a first non-bending region 802, a second non-bending region 803, and a bending region 804 connected to the first non-bending region 802 and the second non-bending region 803. A hardness of a portion of the cover plate in the bending region 804 is less than a hardness of a portion of the cover plate in the first non-bending region 802 and a hardness of a portion of the second non-bending region 803. A buffer layer 805 is disposed between the display panel 801 and the middle frame, and a material of the buffer layer may be foam. The middle frame comprises a left frame 806 and a right frame 807.

The bending region 804 comprises a flexible material and a rigid material (not shown in the figure) arranged spaced apart from each other. The material in the first non-bending region 802 and the second non-bending region 803 is a rigid material, or a combination of a flexible material and a rigid material. The first non-bending region 802 and the second non-bending region 803 of the cover plate of the embodiment are made of a rigid material or a combination of a flexible material and a rigid material, which can improve impact strength of the non-bending region of the flexible display device. And based on this, the bending region 804 is designed as a rigid-flexible alternating structure, which ensures that the impact resistance of the bending region 804 is improved as much as possible without affecting the bending, that is, overall impact resistance of the flexible display device is improved.

In an embodiment, a glass material with higher strength is used in the first non-bending region 802 and the second non-bending region 803 on both sides of the cover plate, and a flexible material such as polyimide, polyethylene terephthalate, etc. are used in the middle bending region 804. A transition region of the two materials can be connected by offset edge overlapping or micro-hole treatment directly by optical glue. Compared with the prior art, the non-bending regions on the two sides of the cover plate of the embodiment can be directly fixed with high temperature glue with a whole device, an operation is simple, and an adhesion stability is improved.

It should be noted that there is more than one bending region in the embodiment, and there may be two or more regions. Accordingly, there are more than two non-bending regions connected to the bending region, which may be three or more. The connection between the non-bending region and the bending region is also similar to any one of the first to sixth embodiments. The transition region can be connected by the offset edge overlapping or the micro-hole treatment directly by the optical glue.

In summary, the cover plate provided in the embodiment of the present invention uses a hard-soft-hard structure, that is, a material with higher strength is used at the non-bending regions on the both sides, and a material with lower strength is used at the middle bending region. With the structure, impact strength of the non-bending regions of the flexible display device can be improved, which solves the technical problems of the prior art that the cover plate of the flexible display device has insufficient impact resistance and the flexible display device is easily damaged due to the use of a flexible substrate.

It can be understood that for a person of ordinary skill in the art, equivalent replacements or changes can be made according to the technical solution of the application and its application concept, and all these changes or replacements should fall within the protection scope of the claims attached to the present application.

What is claimed is:

1. A cover plate, comprising:
a non-bending region and a bending region connected to the non-bending region;
wherein a hardness of a portion of the cover plate disposed in the bending region is less than a hardness of a portion of the cover plate disposed in the non-bending region.

2. The cover plate as claimed in claim 1, wherein a flexible material and a rigid material are arranged spaced apart from each other in the bending region, and a material in the non-bending region is the rigid material, or a combination of the flexible material and the rigid material.

3. The cover plate as claimed in claim 2, wherein a groove is formed in a side of the non-bending region connecting to the bending region, and the flexible material of the bending region extends into the groove.

4. The cover plate as claimed in claim 3, wherein a cross-sectional shape of the groove is triangular, rectangular, or fan-shaped.

5. The cover plate as claimed in claim 4, wherein a depth of the groove is less than or equal to a thickness of the cover plate.

6. The cover plate as claimed in claim 2, wherein the flexible material and the rigid material of the non-bending region are stacked on each other.

7. The cover plate as claimed in claim 6, wherein the flexible material of the non-bending region is disposed on an inner surface or an outer surface of the cover plate.

8. The cover plate as claimed in claim 6, wherein the flexible material in the non-bending region is disposed between two layers of the rigid material.

9. The cover plate as claimed in claim 2, wherein a cross-sectional shape of the rigid material of the bending region is inverted-triangular or trapezoidal.

10. A flexible display device, comprising:
a display panel; and
a cover plate disposed on a light emitting surface of the display panel;
wherein the cover plate comprises a non-bending region and a bending region connected to the non-bending region, and a hardness of a portion of the cover plate disposed in the bending region is less than a hardness of a portion of the cover plate disposed in the non-bending region.

11. The flexible display device as claimed in claim 10, wherein a flexible material and a rigid material are arranged spaced apart from each other in the bending region, and a material in the non-bending region is the rigid material, or a combination of the flexible material and the rigid material.

12. The flexible display device as claimed in claim 11, wherein a groove is formed in a side of the non-bending region connecting to the bending region, and the flexible material of the bending region extends into the groove.

13. The flexible display device as claimed in claim 12, wherein a cross-sectional shape of the groove is triangular, rectangular or fan-shaped.

14. The flexible display device as claimed in claim 13, wherein a depth of the groove is less than or equal to a thickness of the cover plate.

15. The flexible display device as claimed in claim 11, wherein the flexible material and the rigid material of the non-bending region are stacked on each other.

16. The flexible display device as claimed in claim 15, wherein the flexible material of the non-bending region is disposed on an inner surface or an outer surface of the cover plate.

17. The flexible display device as claimed in claim 15, wherein the flexible material in the non-bending region is disposed between two layers of the rigid material.

18. The flexible display device as claimed in claim 11, wherein a cross-sectional shape of the rigid material of the bending region is an inverted-triangle or trapezoidal.
